(19) United States
(12) Patent Application Publication
(10) Pub. No.: US 2017/0256692 A1
(43) Pub. Date: Sep. 7, 2017

(54) FLEXIBLE LIGHT EMITTING DEVICE

(71) Applicant: PHILIPS LIGHTING HOLDING B.V., EINDHOVEN (NL)

(72) Inventors: TIES VAN BOMMEL, HORST (NL); RIFAT ATA MUSTAFA HIKMET, EINDHOVEN (NL)

(21) Appl. No.: 15/512,083

(22) PCT Filed: Sep. 7, 2015
(86) PCT No.: PCT/EP2015/070313

§ 371 Date: Mar. 17, 2017

(30) Foreign Application Priority Data
Sep. 17, 2014 (EP) 14185062.8

(51) Int. Cl. H01L 33/60; H01L 33/24; H01L 33/50

(52) U.S. Cl. CPC H01L 33/60; H01L 33/502; H01L 33/24

(57) ABSTRACT

The present invention relates to a light emitting device (100) having a first light exit window and comprising a flexible light source having a first surface (11) facing the first light exit window and arranged to emit light at least in a direction of the first light exit window, and a plurality of first optical elements (30) provided on the first surface (11) of the flexible light source and arranged to change a value of at least one optical parameter of at least a part of the light emitted by the flexible light source, wherein a distance (91, 92) between adjacent first optical elements (30) depends on a shape of the flexible light source. This provides for a light emitting device wherein a value of an optical parameter can be changed by changing the shape of the flexible light source and wherein the value of the at least one optical parameter of the light emitted by the light emitting device is different for a first shape of the flexible light source as compared to a second shape of the flexible light source, the first shape being different from the second shape.

### FIELD OF THE INVENTION

The present invention relates to a flexible light emitting device.

### BACKGROUND OF THE INVENTION

Fluorescent and incandescent lighting are commonly used lighting technologies for various lighting applications such as for example illumination of an office space or a shopping mall. However, incandescent lighting is not competitively energy efficient and fluorescent lighting tubes commonly contain environmentally unfriendly elements that are not easily disposed of In recent years, solid state light sources, such as light emitting diodes (LEDs), have emerged as a strong competitor on the market for lighting applications, mainly due to their superior energy efficiency over other existing technologies.

In some applications it may desirable to be able to modify one or more optical characteristics of the light emitting device, for example optical parameters or variables like color, intensity and/or direction of the emitted light. A solution is to use driver electronics that drives the solid state light sources with different currents and/or to use light sources that emit different colors. However, this limits the possibilities of changing the optical characteristics to the ones that are delivered with the light emitting device.

Thus, there is a need for a light emitting device with increased freedom of design in adapting some of its optical characteristics.

### SUMMARY OF THE INVENTION

In view of the above mentioned and other drawbacks of the prior art, a general object of the present invention is to provide a light emitting device in which one or more of the optical characteristics, such as color and/or direction of the emitted light, is easy to adapt.

According to a first aspect of the present invention there is provided a light emitting device having a first light exit window and comprising a flexible light source having a first surface facing the first light exit window and arranged to emit light in a direction of the first light exit window, and a plurality of first optical elements provided on the first surface of the flexible light source and arranged to change a value of at least one optical parameter of at least a part of the light emitted by the flexible light source, wherein a distance between adjacent first optical elements depends on a shape of the flexible light source and wherein the value of the at least one optical parameter of light emitted by the light emitting device is different for a first shape of the flexible light source as compared to a second shape of the flexible light source, the first shape being different from the second shape.

In accordance with the invention, a light emitting device is provided in which a value of an optical parameter, which represents one or more optical characteristics of the light emitting device, of the light emitted via the first light exit window is/are changed by changing the shape of the flexible light source. Because the plurality of first optical elements are arranged on the first surface of the flexible light source, the first optical elements face the first light exit window, and are thus arranged in between the first surface from which (in operation) light is emitted and the first light exit window. Because the distance between adjacent or neighboring first optical elements depends on the shape of the flexible light source, a change of the shape of the flexible light source results in a change of the distance between the individual first optical elements and, hence, changes a value of one or more of the optical characteristics, or optical parameters or properties, of the plurality of first optical elements. In this way a value of an optical parameter of the light emitting device may be adjusted by changing the shape of the flexible light source. Hence, the optical properties of the emitted light will change when the shape changes. For example, when the flexible light source is formed as the first shape, then adjacent first optical elements are spaced with a first distance and when the flexible light source is shaped as the second shape, which is different from the first shape, then the adjacent first optical elements are spaced with a second distance, the second distance being different from the first distance. Light that is emitted in a direction that is in between the first optical elements, i.e. in a direction of the spacing, or distance, between the first optical elements, is not or to a limited amount affected, e.g. redirected, by the first optical elements. By changing the distance, or spacing, between the first optical elements, the amount of light that is not affected, e.g. redirected, by the first optical elements is changed and consequently also the amount of light that is affected, e.g. redirected, by the first optical elements is changed and, hence, the one or more optical characteristics of the plurality of first optical elements are changed resulting in a change of a value of at least one optical parameter or property of at least part of the light emitted by the light emitting device, for example color, brightness and/or direction of the light. Thus a light beam that exits the light emitting device via the exit window will have an optical property or characteristic that depends on the shape of the flexible light source. For example, the first shape of the flexible light source will result in a first light beam and the second shape of the flexible light source will result in a second light beam that exits the light emitting device. The first light beam and the second light are different with respect to at least one optical property or parameter, for example the first light beam has a first color and the second light beam has a second color that is different from the first color, and/or the first light beam has a first beam width and the second light beam has a second beam width that is different from the first beam width, etc. Thus, the flexible light source is shapeable and can be formed into another shape, for example by flexing or bending the light source in one or more directions, which results in a changed and different distance between adjacent first optical elements resulting in changed optical characteristics or properties of the light emitted by the light emitting device. The shape may be any shape such as a flat shape, an arc-like shape, a generally cylindrical shape a multi-angled shape, such as a hexagonal or octagonal shape. In an embodiment the flexible light source has a shape comprising a plurality of flat regions that have an angle different from 180 degrees with respect to each other. The plurality of first optical elements may be considered as being a first optical device of which the optical characteristics depend on the distance between the first optical elements. A change in distance between the first optical elements, and hence a change of the optical characteristics, is affected by changing the shape of the flexible light source on which the plurality of first optical elements, and thus the first optical device, are provided. Thus, the shape of the flexible light source defines the optical characteristics, or a value of an optical parameter, or optical property, of the plurality of first optical elements.

The first optical elements are arranged to change a value of an optical parameter of at least a part of the light emitted by the flexible light source, for example, the first optical elements may comprise a reflective element, changing the direction of the light, or a light scattering element, e.g. a wavelength converting element, changing the color of the light and/or redirecting the light. The first optical elements may for example be manufactured by a suitable 3D printing technique.

The flexible light source may be, for example, a flexible OLED plate or a plurality of light sources comprising a flexible substrate.

According to an embodiment of the invention the flexible light source is at least partly transparent and the light emitting device further comprises a second light exit window facing a second surface of the flexible light source, which second surface is opposite to the first surface of the flexible light source, wherein the first optical elements are further arranged to redirect at least a part of the light emitted by the flexible light source in a direction of the second light exit window. The flexible light source being at least partly transparent means that at least a part of the flexible light source is transparent for visible light. This advantageously provides for a light emitting device from which the light is emitted in two directions, i.e. in a first direction of the first light exit window comprising light emitted by the flexible light source and partly redirected by the first optical elements, and in a second direction of the second light exit window comprising light redirected by the first optical elements. Hence, according to this embodiment two light beams in two substantially opposite directions can be emitted by the light emitting device. Thus the light emitting device according to this embodiment enables the altering of the optical characteristics, or a value of at least one optical parameter or property, of light emitted in two different directions, i.e. of light emitted into a direction of the first light exit window and of light emitted into a direction of the second light exit window. For example, when the flexible light source is formed as a first shape then adjacent first optical elements are spaced with a first distance and when the flexible light source is shaped as a second shape, which is different from the first shape, then the adjacent first optical elements are spaced with a second distance, the second distance being different from the first distance. Light that is emitted in a direction that is in between the first optical elements, i.e. in a direction of the spacing, or distance, between the first optical elements is not or to a limited amount redirected to the second light exit window by the first optical elements. By changing the distance, or spacing, between the first optical elements, the amount of light that is not redirected to the second light exit window by the first optical elements is changed, e.g. increased or decreased, and consequently also the amount of light that is redirected to the second light exit window by the first optical elements is changed, e.g. decreased or increased, and, hence, a value of an optical parameter, or optical characteristic or property, is changed both of light emitted by the light emitting device into a direction of the first light exit window and of light emitted by the light emitting device into a direction of the second light exit window. In other words, there may be two light beams that are emitted from the light emitting device in two substantially opposite directions and a value of at least one optical parameter, or property, of each of the two light beams depends on the shape of the flexible light source.

According to an embodiment of the invention the flexible light source comprises a flexible light guide and wherein a plurality of outcoupling structures are provided at or on the flexible light guide. The flexible light guide may receive light from one or more solid state light sources. The outcoupling structures may be, for example, luminescent elements. The first surface of the flexible light source corresponds to a surface of the flexible light guide at or on which the outcoupling structures are provided. In an embodiment the flexible light guide is at least partly transparent for light received at the first surface, and light that is redirected by the first optical elements in a direction of the second light exit window can be transmitted through the flexible light guide and exits and another surface.

According to an embodiment of the invention the flexible light source comprises a plurality of solid state light sources provided on a flexible substrate. The plurality of solid state light sources is, for example, arranged as a linear array wherein the light sources have a fixed pitch. The first surface of the flexible surface corresponds to a surface of the flexible substrate and the plurality of solid state light sources are provided on the first surface of the flexible substrate. In an embodiment the plurality of first optical elements are arranged in alignment with the plurality of light sources, i.e. each solid state light source is associated with one first optical element, or each solid state light source is arranged in between two first optical elements.

The light source may be a semiconductor based light source such as a light emitting diode, a laser diode, OLED.

According to an embodiment of the invention the flexible light source comprises a plurality of solid state light sources provided on a flexible and at least partially transparent substrate. The first surface of the flexible surface corresponds to a surface of the flexible and at least partially transparent substrate and the plurality of solid state light sources are provided on the first surface of the flexible substrate. An at least partially transparent substrate, i.e. a substrate at least a part of which transmits visible light, provides for a light emitting device in which the light emitted by the solid state light sources can be transmitted through the substrate in a direction opposite to the direction in which the light sources emit light. For example, the plurality of solid state light sources are arranged to emit light into a direction of the first light exit window and a part of this light is redirected by the first optical elements into a direction of the substrate and then transmitted through the at least partially transparent substrate into a direction of the second light exit window. Thus the first light exit window and second light exit window are located on opposite sides of the at least partially transparent substrate.

According to an embodiment of the invention the plurality of first optical elements are arranged in alignment with the plurality of light sources. In this way an optimum collimation of light emitted by the solid state light sources may be achieved. In another embodiment the first optical elements are arranged with a first spacing and the solid state light sources are arranged with a second spacing, the first spacing being different from the second spacing. In another embodiment the light sources are arranged in between the first optical elements.

According to an embodiment of the invention at least one of the plurality of first optical elements comprises a reflective element. In this way, a redirection of the emitted light is provided for and the amount of light that is redirected depends on the shape of the flexible light source.

According to an embodiment of the invention at least one of the plurality of first optical elements comprises a wavelength converting element. In this way, in addition to redirecting, or scattering, of the light emitted by the flexible light source, also the color characteristics of the light emitted by the light emitting device may be altered by changing the shape of the flexible light source and thereby the distance between the wavelength converting elements.

According to an embodiment of the invention at least one of the plurality of first optical elements is reflective for a first range of wavelengths and transmissive for a second range of wavelengths which is different from the first range of wavelengths. In this way both the color characteristics and the light direction and brightness distribution of the light emitted by the light emitting device may be altered by changing the shape of the flexible light source and thereby the distance between the first optical elements.

According to an embodiment of the invention the light emitting device further comprises a plurality of second optical elements on the second surface of the flexible light source, and wherein a distance between adjacent second optical elements depends on the shape of the flexible light source. In this embodiment at least a part of the flexible light source is transparent for light. The second optical elements thus face the second light exit window and are provided in between the second surface of the flexible light source and the second light exit window. The second optical elements provide for an additional degree of freedom in altering the optical characteristics of the light emitting device by changing the value of at least one optical parameter, or property, of at least part of the light that is emitted into the direction of the second light exit window induced by a change of the shape of the flexible light source. The second optical elements may comprise a reflective element, a wavelength converting element, or any other type of optical element as described above and below with respect to the first optical elements. Furthermore, the shape of the second optical elements may be any shape as described in relation to the first optical elements.

For example, when the flexible light source is formed as a first shape then adjacent first optical elements are spaced with a first distance and adjacent second optical elements are spaced with a third distance. When the flexible light source is shaped as a second shape, which is different from the first shape, then the adjacent first optical elements are spaced with a second distance and the adjacent second optical elements are spaced with a fourth distance, the second distance being different from the first distance and the third distance being different from the fourth distance. These different distances result in at least one different optical characteristic or property, and different values of at least one optical parameter of the light emitted by the light emitting device both into a direction of the first light exit window and of light emitted by the light emitting device into a direction of the second light exit window.

According to an embodiment of the invention the first optical elements have a pyramid or cone shape having a flattened top surface wherein a base of the pyramid or cone shape is arranged on the first surface of the flexible light source and wherein the distance between adjacent optical elements is defined by the spacing between the flattened top surfaces. The spacing or distance between neighboring or adjacent pyramid or cone shaped optical elements may be defined as the shortest distance between the, in this case flattened, top surface of the pyramid or cone shapes. For a particular shape of the flexible substrate the distance between the pyramid or cone shaped optical elements is greater than zero and thus an opening is defined between the tops of the pyramids or cones. In this case light emitted by the flexible light source is a mixture of light that is affected by the first optical elements and light that is not affected by the first optical elements because this part of the light exits the first light exit window via the openings in between adjacent pyramids or cones. The flexible substrate may also be shaped such that the distance between the top surfaces and side surfaces of the pyramid or cone shaped optical elements is zero, or, in other words, such that the top surfaces and side surfaces of neighboring or adjacent pyramid or cone shaped optical elements are adjoining. In this case there is no opening between the first optical elements and all emitted light is affected by the first optical elements. On the flattened top surface of the first optical elements a redirection element, a reflective element or a wavelength converting element may be provided. The distance between the base or bottom surface of the pyramid or cone shaped optical elements may be zero, i.e. the first optical elements adjoin each other on the first surface of the flexible light source, or there may be a spacing in between the base surfaces of the neighboring optical elements. In other embodiments the pyramid or cone shaped first optical elements do not have a flattened top surface. In another embodiment the first optical elements are shaped as cylinders.

According to an embodiment of the invention the flexible light source is adapted to be shaped as a cylindrical shape. This provides for a light emitting device which may emit light all around the cylindrically shaped device. In one example the first surface of the flexible substrate corresponds to an outward facing surface of the cylindrical shape of the flexible substrate.

According to an embodiment of the invention the plurality of first optical elements are arranged in a 2-dimensional array. This arrangement in rows and columns provides for an additional degree of freedom to change one or more optical characteristics, for example a 2-dimensional light distribution, by changing the shape of the flexible light source in two directions. In an embodiment the plurality of light sources are also arranged in a 2-dimensional array.

According to an embodiment of the invention the light emitting device further comprises connection means arranged to fixate a predefined shape of the flexible light source. In this way the light emitting device may be fixated in a predefined shape which corresponds to predefined optical characteristics, or a predefined value of an optical parameter, for example a predefined light distribution, emitted from the first light exit window and optionally also from the second light exit window. The connection means is arranged to fixate the light emitting device into a different predefined shape, in case different optical characteristics are required, such as for example a different light distribution.

According to an embodiment of the invention the flexible light source is further arranged to emit light also into a direction of the second light exit window. The value of at least one optical parameter, or property, of at least part of light emitted by the light emitting device via the second light exit window is different for the first shape of the flexible light source as compared to the second shape of the flexible light source. This provides for an increased flexibility in controlling the directionality and optical characteristics of the light. In an embodiment a plurality of second light sources is arranged on a surface of the flexible and at least partially transparent substrate which is opposite to the surface on which the plurality of first light sources is arranged. In another embodiment light outcoupling features are provided at or on two opposite surfaces of a light guide. In yet another embodiment an OLED is provided which emits light from two opposite surfaces.

The invention also relates to a luminaire comprising a light emitting device according to any of the embodiments listed above.

According to a second aspect of the present invention there is provided a method of changing a value of at least one optical parameter of at least part of light emitted by a light emitting device having a first light exit window and comprising a flexible light source having a first surface facing the first light exit window and arranged to emit light in a direction of the first light exit window, and a plurality of first optical elements provided on the first surface of the flexible light source, the method comprising the steps of changing the flexible light source from a first shape to a second shape, thereby changing a distance between adjacent first optical elements and changing a value of an optical parameter of at least a part of the light emitted by the light emitting device.

Further features of, and advantages with, the present invention will become apparent when studying the appended claims and the following description. The skilled person realize that different features of the present invention may be combined to create embodiments other than those described in the following, without departing from the scope of the present invention.

### BRIEF DESCRIPTION OF THE DRAWINGS

These and other aspects of the present invention will now be described in more detail, with reference to the appended drawings showing exemplary embodiments of the invention, wherein:

FIGS. 1A, 1B, 1C schematically show an exemplary embodiment of different shapes of a light emitting device according to the present invention;

FIGS. 2A, 2B, 2C schematically show an exemplary embodiment of different shapes of a light emitting device according to the present invention;

FIG. 3 schematically shows an exemplary embodiment of a light emitting device according to the present invention;

FIG. 4 schematically shows an exemplary embodiment of a light emitting device according to the present invention;

FIG. 5 schematically shows an exemplary embodiment of a light emitting device according to the present invention;

FIG. 6 schematically shows an exemplary embodiment of a light emitting device according to the present invention;

FIG. 7 schematically shows an exemplary embodiment of a light emitting device according to the present invention;

FIG. 8 schematically shows an exemplary embodiment of a light emitting device according to the present invention;

FIG. 9 schematically shows an exemplary embodiment of a light emitting device according to the present invention;

FIG. 10 schematically shows an exemplary embodiment of a light emitting device according to the present invention;

FIGS. 11A, 11B schematically show an exemplary embodiment of different shapes of a light emitting device according to the present invention;

FIGS. 12A, 12B, 12C schematically show an exemplary embodiment of different shapes of a light emitting device according to the present invention;

FIGS. 13A, 13B schematically show an exemplary embodiment of different shapes of a light emitting device according to the present invention;

FIG. 14 schematically shows an exemplary embodiment of a light emitting device according to the present invention; and

FIG. 15 schematically shows an exemplary embodiment of a light emitting device according to the present invention.

### DESCRIPTION OF EXAMPLE EMBODIMENTS OF THE PRESENT INVENTION

The present invention will now be described more fully hereinafter with reference to the accompanying drawings, in which currently preferred embodiments of the invention are shown. This invention may, however, be embodied in many different forms and should not be considered as limited to the embodiments set forth herein; rather, these embodiments are provided for thoroughness and completeness, and fully convey the scope of the invention to the skilled person. Like reference characters refer to like elements throughout.

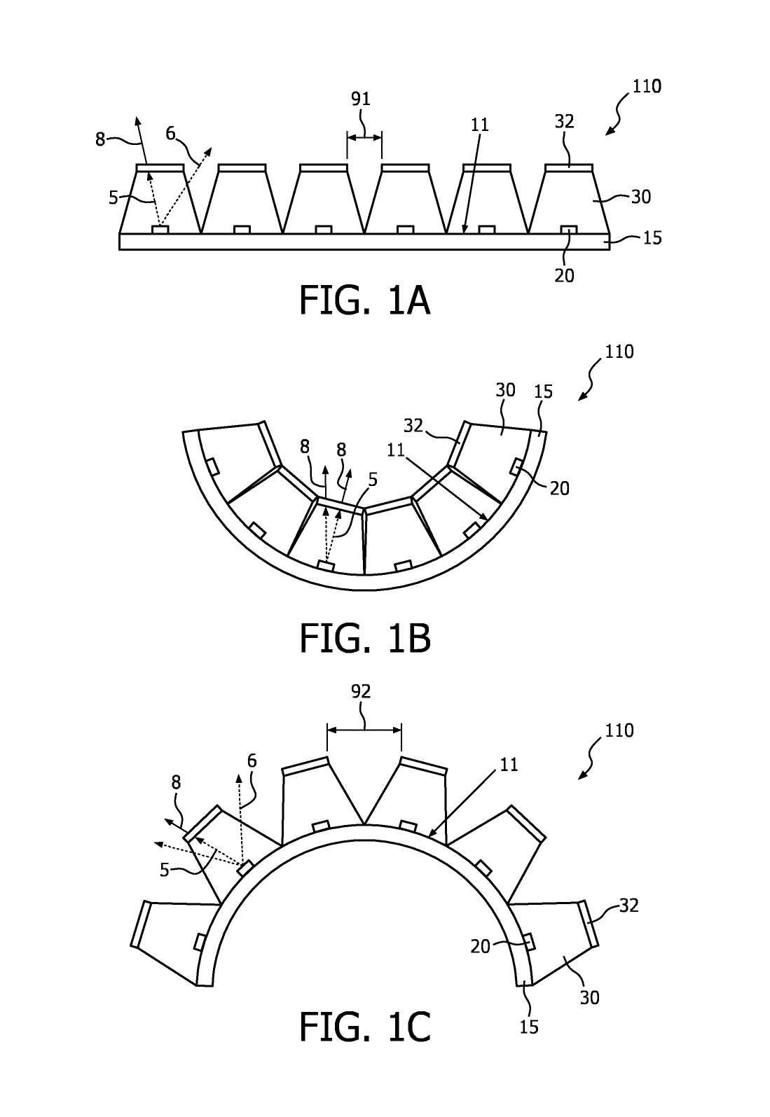

FIGS. 1A, 1B and 1C show schematic drawings of different shapes of a light emitting device 110 according to an embodiment the invention. The light emitting device 110 comprises a plurality of solid state light sources, in this example light emitting diodes 20, arranged on a flexible substrate 15. The substrate 15 is made of a suitable flexible material and is arranged to be bended or flexed into another 2-dimensional or 3-dimensional shape. The bending or flexing of the substrate into another shape may be done via user interaction or via any suitable control, e.g. mechanically, device. The substrate 15 is in this embodiment not transparent, it may for example be a reflective substrate or a substrate with a reflective layer. The light emitting device 110 further comprises a plurality of first optical elements 30 each provided with a wavelength converting element 32 arranged to convert the wavelength range of light emitted by the light emitting diodes 20 to another wavelength range. The first optical elements 30 are in this case pyramid, or cone, shaped wherein each base of the pyramid or cone shaped first optical element 30 is arranged on a first surface 11 of the flexible substrate 15. The first optical elements may comprise a transparent material such as, for example, polymers, glass, PMMA, polycarbonate, silicones, cross-linked polymers. The pyramid or cone shaped first optical elements 30 have a flattened top surface on which the wavelength converting element 32 is arranged. The first optical elements may have other shapes, such as cylinders, cones, blocks, and may be manufactured e.g. via 3d printing. Examples of wavelength converting elements 32 are organic and inorganic phosphors and quantum dots.

The light emitting device has a first light exit window (not shown). The first optical elements 30, and also the wavelength converting elements 31, are facing the first light exit window, or, in other words, the first light exit window is at a side of the first surface 11 of the substrate 15. The light exit window defines areas of the light emitting device 110 where light is emitted in case the light emitting device is in operation. Thus, the light emitting device 110 is arranged to emit light via the first light exit window.

In this embodiment the bases of the first optical elements 30 are adjoining on the first surface 11 of the substrate 15, but in other embodiments (not shown) the bases of the first optical elements 30 are arranged with a spacing in between, i.e. spaced apart.

In this embodiment the first optical elements 30 are arranged in alignment with the light emitting diodes 20, i.e. each light emitting diode 20 is provided with a first optical element 30. In another embodiment two or more light emitting diodes 20 are provided with one first optical element 30. In another embodiment the light emitting diodes 20 are arranged in between the first optical elements 30 which are spaced apart. In yet other embodiments the first optical elements are spaced with a different spacing than the light emitting diodes.

FIG. 1A shows a first shape of the flexible substrate 15, FIG. 1B shows a second shape of the flexible substrate 15, and FIG. 1C shows a third shape of the flexible substrate 15. The first shape of the flexible substrate 15, as shown in FIG. 1A, is an initial shape which is a linear or 2-dimensional and generally flat shape in which the flexible substrate 15 is not bended or flexed. The first shape of the flexible substrate 15 results in the first distance 91 between the first optical elements 30, for example defined as the shortest distance between the wavelength converting elements 32. A part of light emitted by the light emitting diodes 20 is incident on the wavelength converting elements 32, as indicated by arrow 5 in the figure. Part of the light entering the wavelength converting elements 32 is redirected and converted to another wavelength range and emitted from the wavelength converting elements 32 in a direction of the first light exit window and subsequently exits the light emitting device 110 via the first light exit window, as indicated by arrow 8 in the figure. Another part of the light emitted by the light emitting diodes 20 is transmitted in between the first optical elements 30, i.e. in this case via the spacing in between the wavelength converting elements 32 (no wavelength conversion), and is thus not affected by at least a part of the first optical elements 30 and/or by the wavelength converting elements 32 and exits the light emitting device via the first light exit window, as indicated by arrow 6 in the figure. Another part of the light that enters the wavelength converting elements 32 is redirected in a direction of the flexible substrate 15 and may be reflected from the substrate into a direction of the first light exit window (not shown). A part of this redirected light is converted and another part is not converted. The first shape thus provides for a light emitting device that partly converts light emitted by the light sources and partly does not, or to a limited extent, convert the light emitted by the light sources resulting in a first mixture of converted and unconverted light emitted by the light emitting device.

The second shape of the flexible substrate 15, as shown in FIG. 1B, which is in this case an arc-like shape, or partly cylindrical or hexagonal or octagonal shape, in which the flexible substrate 15 is flexed or bended inwards into a direction of the first optical elements 30, results in adjoining first optical elements 30 and, in this case, also adjoining wavelength converting elements 32. In this embodiment all light emitted by the light emitting diodes 20, as indicated by arrow 5 in the figure, is incident on the wavelength converting elements 32 and a major part of the incident light will be converted to another wavelength range and subsequently exits the light emitting device 110 via the first light exit window, as indicated by arrows 8, and another part of the incident light will be redirected, partly converted, into a direction of the substrate 15 and subsequently reflected back into a direction of the wavelength converting elements 32 (not shown). Hence, in this case all light emitted by the light emitting diodes 20 is affected, and hence converted, by the wavelength converting elements 32. The second shape thus provides for a light emitting device that converts light emitted by the light sources resulting in a second mixture of converted and unconverted light emitted by the light emitting device which is different from the first mixture, i.e. relatively more light for this second shaped is converted than for the first shape.

The third shape of the flexible substrate 15, as shown in FIG. 1C, is in this case an arc-like shape, or partly cylindrical or hexagonal or octagonal shape, in which the flexible substrate 15 is flexed or bended outwards into a direction away from the first optical elements 30, which is opposite to the bending direction of the second shape. The third shape results in the second distance 92 between the first optical elements 30, which is for example defined as the shortest distance between the wavelength converting elements 32. The second distance 92 is in this case larger than the first distance 91 and therefore a smaller amount of light emitted by the light emitting diodes 20 is affected by the wavelength converting elements 32 in case the flexible substrate 15 has the third shape as compared to the first shape, and also compared to the second shape. As a result of the changed amount of converted light, the color of the light emitted via the first light exit window for the first shape is different from the color of the light emitted via the first light exit window for the third shape, and the color of the light emitted via the first light exit window for the second shape is different from the color of the light emitted via the first light exit window for the third shape. The third shape thus provides for a light emitting device that converts light emitted by the light sources resulting in a third mixture of converted and unconverted light emitted by the light emitting device which is different from the first and the second mixture, i.e. relatively less light is converted for this third shaped than for the first shape. Thus, by having the light emitting device with a different shape the color characteristics of light emitted via the first light exit window are different. For example, a luminaire comprising such a light emitting device 110, can be used as a luminaire in which the color of the emitted light can be tuned by the shape of the light emitting device 110.

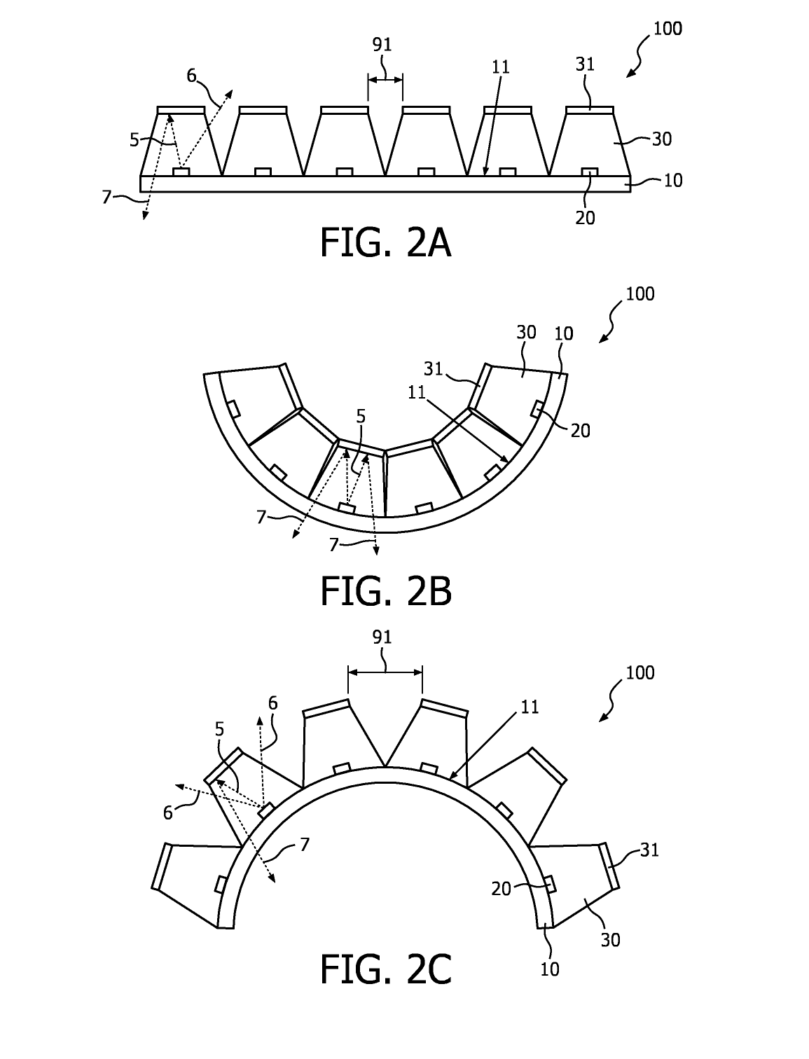

FIGS. 2A, 2B and 2C show schematic drawings of different shapes of a light emitting device 100 according to an embodiment the invention. A difference with the embodiments shown in FIGS. 1A, 1B and 1C is that the wavelength converting elements 32 are replaced by reflective elements 31. Another difference is that the flexible substrate is in this case at least partly transparent, meaning that at least a part of the flexible substrate 10 is transparent for visible light. The substrate 10 is for example made of plastic, e.g. PMMA, PC, PET, or glass.

The light emitting device 100 in this embodiment comprises the first light exit window and, additionally, a second light exit window (not shown in the figures). The first optical elements 30, and also the reflective elements 31, are facing the first light exit window, or, in other words, the first light exit window is at a side of the first surface 11 of the substrate 10. The second light exit window is opposite to the first light exit window, and faces a surface of the substrate 10 that is opposite to the first surface 11. The first and second light exit windows define areas of the light emitting device 100 where light may be emitted. Thus, the light emitting device 100 is arranged to emit light via the first light exit window and via the second light exit window.

FIG. 2A shows a first shape of the flexible substrate 10, FIG. 2B shows a second shape of the flexible substrate 10, and FIG. 1C shows a third shape of the flexible substrate 10. The first shape of the flexible substrate 10, as shown in FIG. 2A, is an initial shape which is a linear or 2-dimensional shape and generally flat shape in which the flexible substrate 10 is not bended or flexed. The first shape results in the first distance 91 between the first optical elements 30, for example defined as the shortest distance between the reflective elements 31. A part of light emitted by the light emitting diodes 20 is incident on the reflective elements 31, as indicated by arrow 5 in the figure, and is redirected in a direction of the flexible substrate 10 and a part of this light is transmitted through the partly transparent and flexible substrate 10 and subsequently exits the light emitting device via the second light exit window, as indicated by arrow 7 in the figure. Another part of the light emitted by the light emitting diodes 20 is transmitted in between the first optical elements 30, i.e. in this case via the spacing in between the reflective elements 31, and is not affected by the first optical elements 30 and/or the reflective elements 31 and exits the light emitting device via the first light exit window, as indicated by arrow 6 in the figure.

The second shape of the flexible substrate 10, as shown in FIG. 2B, which is in this case an arc-like shape, or partly cylindrical shape, in which the flexible substrate is flexed or bended inwards into a direction of the first optical elements 30, results in adjoining first optical elements 30 and, in this case, also adjoining reflective elements 31. In this embodiment all light emitted by the light emitting diodes 20, as indicated by arrow 5 in the figure, is reflected by the reflective elements 31 into a direction of the at least partially transparent substrate 10 and is subsequently transmitted through the at least partially transparent substrate 10 and exits the light emitting device 100 via the second light exit window, as indicated by arrow 7 in the figure. Hence, in this case all light is emitted via the second light exit window.

The third shape of the flexible substrate 10, as shown in FIG. 2C, which is in this case an arc-like shape, or partly cylindrical shape, in which the flexible substrate is flexed or bended outwards into a direction away from the first optical elements 30, which is opposite to the bending direction of the second shape. This results in the second distance 92 between the first optical elements 30, which is for example defined as the shortest distance between the reflective elements 31. The second distance 92 is in this case larger than the first distance 91 of the first shape and therefore a smaller amount of light emitted by the light emitting diodes 20 is affected by the reflective elements 31 in case the flexible substrate has this third shape. As a result of the reduced amount of light reflected by the reflective elements 31, the amount of light emitted via the first light exit window is increased (with respect to the first shape), and the amount of light emitted via the second light exit window is decreased for this third shape as compared to the first shape. Thus, by having a light emitting device with a different shape an optical characteristic or property, or a value of an optical parameter, emitted via the first light exit window and the second light exit window are different, in this case for example the amount of light, i.e. the brightness. For example, a luminaire comprising such a light emitting device 100, can be used as an up-down luminaire in which the light is emitted in two, opposite directions, and the ratio of the brightness in both directions can be tuned by the shape of the light emitting device 100.

In an embodiment (not shown) the reflective elements 31 are selectively reflective, i.e. the reflective elements 31 are arranged to reflect a part of a visible wavelength range and are transmissive for a remaining wavelength range.

In an embodiment (not shown) the reflective elements 31 of light emitting device 100 are replaced by wavelength converting elements 32, in which case both the color of the light emitted via the first light exit window and the color of the light emitted via the second light exit window can be tuned by the shape of the light emitting device. In another embodiment a combination of reflective and wavelength converting elements are provided, e.g. a wavelength converting element and a reflective element alternately provided on the first optical elements.

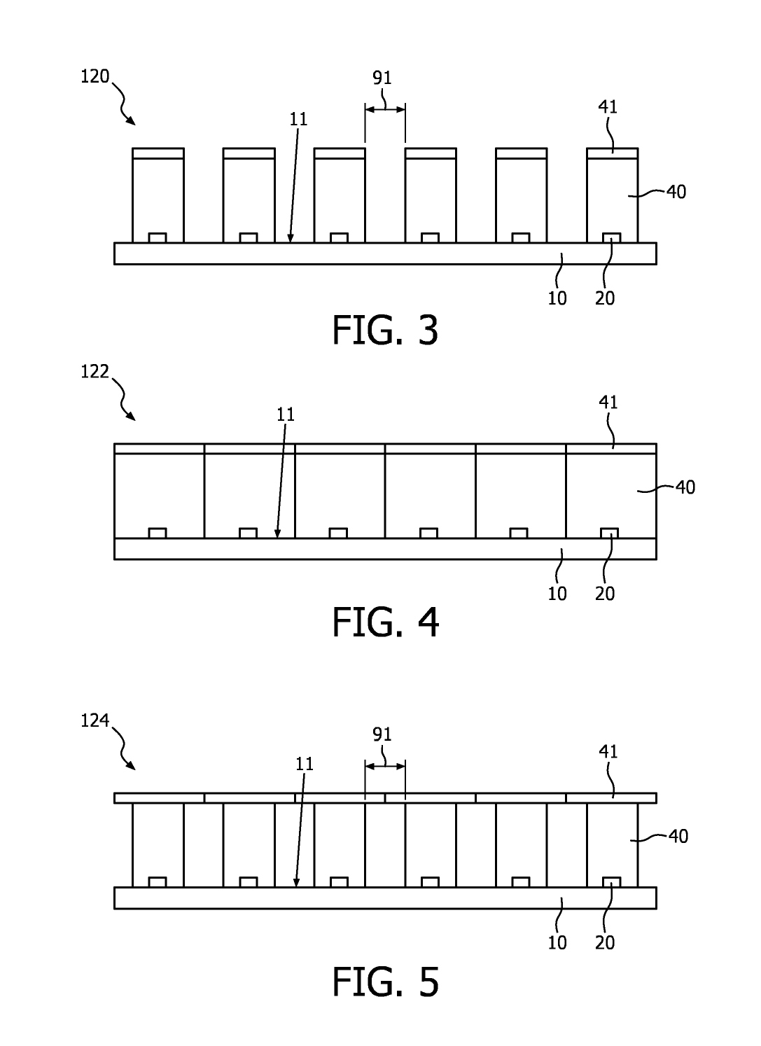

The shape of the first optical elements in the above described embodiments with respect to FIGS. 1 and 2 is a pyramid or cone shape. In other embodiments the first optical elements have other appropriate shapes, such as cylinder shapes, which may be manufactured using 3D printing techniques, such as additive manufacturing techniques. FIGS. 3, 4 and 5 show, as examples, schematic drawings of block shaped first optical elements 40 of a light emitting device 120, 122, 124 wherein on top of the first optical elements 40 reflective elements 41 are arranged. The flexible and, optionally, at least partly transparent substrate 10 is not flexed or bended, and has an initial shape which is a generally flat shape in which the first optical elements 40, and also the reflective elements 41, are spaced with a first distance 91. In other embodiments the reflective elements 41 are replaced by wavelength converting elements or any other suitable optical elements. The light emitting device 120 shown in FIG. 3 may have elements similar to those shown in FIG. 1 and FIG. 2. In the embodiment of FIG. 4 the block shaped first optical elements 40 and the reflective elements 41 are adjoining in the initial state. In this embodiment the flexible substrate 10 can only be bended or shaped into one direction, i.e. the direction of the second light exit window, because the first optical elements 40 inhibit (block) a flexing or shaping of the flexible substrate 10 into a direction of the first light exit window. In the embodiment of FIG. 5 the block shaped first optical elements 40 are spaced with the first distance 91 and the reflective elements 41 are adjoining in the initial state. In this embodiment the reflective elements 41 have a larger surface area than a surface area of the top of the first optical elements 40.

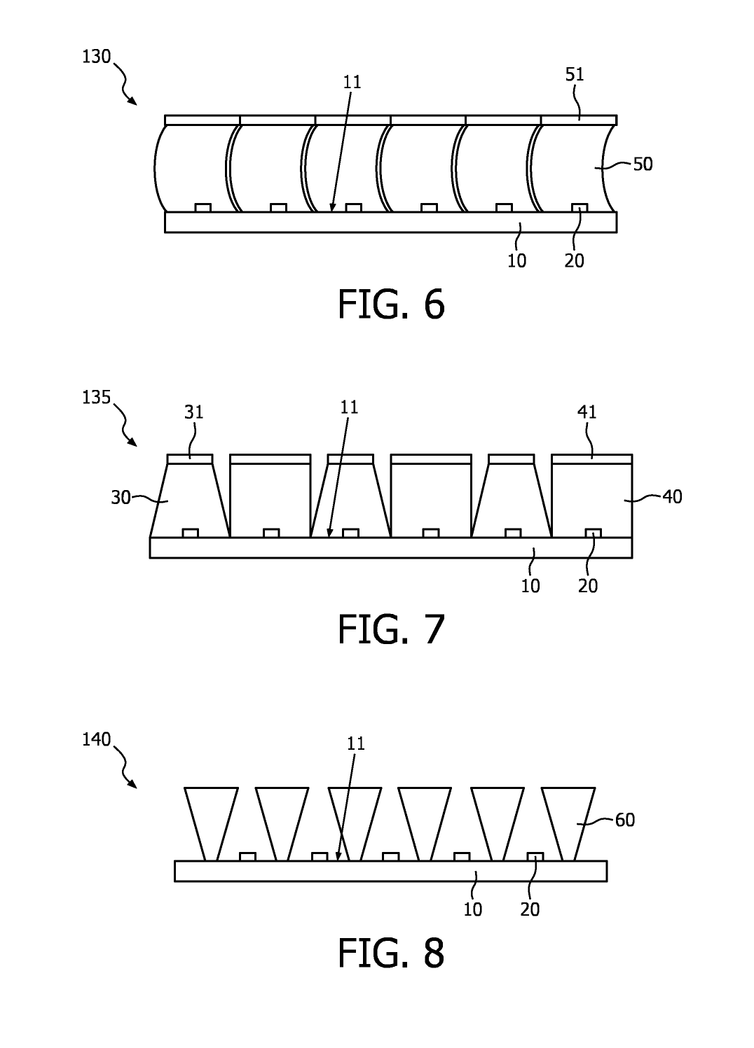

FIG. 6 shows as an example a schematic drawing of arc shaped first optical elements 50 of a light emitting device 130 wherein on top of the first optical elements 50 reflective elements 51 are arranged.

FIG. 7 shows as an example a schematic drawing of a light emitting device 135 comprising alternately pyramid shaped first optical elements 30 with first reflective elements 31 and block shaped first optical elements 40 with second reflective elements 41.

FIG. 8 shows as an example a schematic drawing of a light emitting device 140 comprising pyramid or cone shaped first optical elements 60 wherein a flattened top surface of the first optical elements is arranged on the first surface 11 of the flexible substrate 10 and a base of the first optical elements 60 faces the first light exit windows. Furthermore, the light emitting diodes 20 are provided in between the first optical elements 60 on the first surface 11 of the flexible substrate 10.

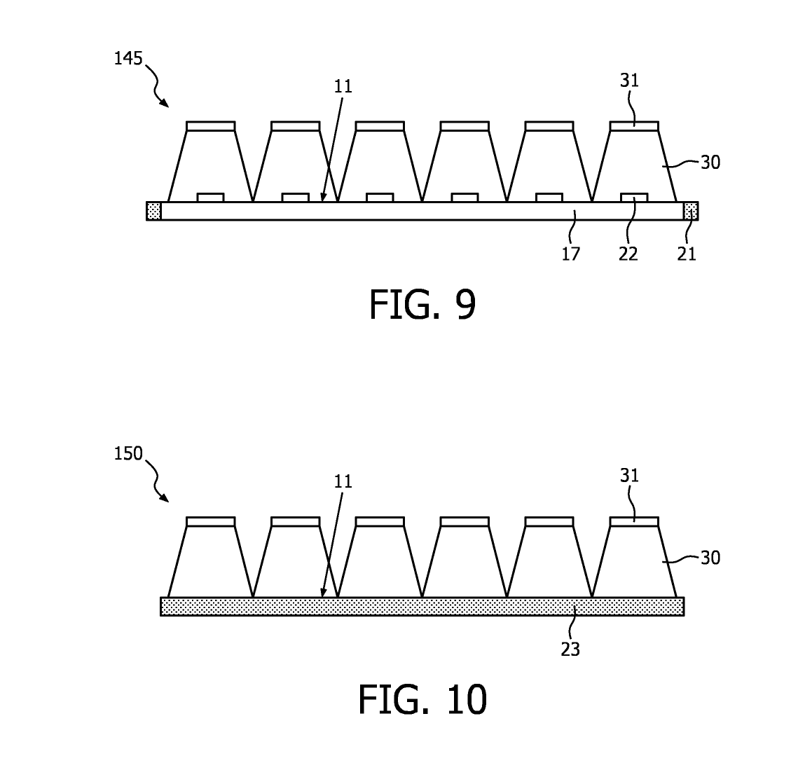

FIG. 9 shows a schematic drawing of a light emitting device 145 according to an embodiment the invention. The difference with the embodiments shown in FIG. 2 is that the flexible and at least partly transparent substrate 10 and the light emitting diodes 20 are replaced by a flexible light guide 17 receiving light from solid state light emitters 21, for example light emitting diodes, and light out-coupling elements 22 for coupling light out of the flexible light guide 17 into a direction of the first optical elements 30 and the first light exit window. The flexible light guide 17 is, for example, made of plastic, e.g. PMMA, PC, PET, or glass. In an embodiment the light guide also comprises a cladding layer with low refractive index. The out-coupling elements 22 comprise, for example, luminescent elements, surface structures, diffractive patterns, scattering areas, and/or roughened areas.

FIG. 10 shows a schematic drawing of a light emitting device 150 according to an embodiment the invention. The difference with the embodiments shown in FIG. 1 is that the flexible substrate 10 and the light emitting diodes 20 are replaced by a flexible OLED device 23 arranged to emit light into a direction of the first light exit window and optionally also into a direction of the second light exit window.

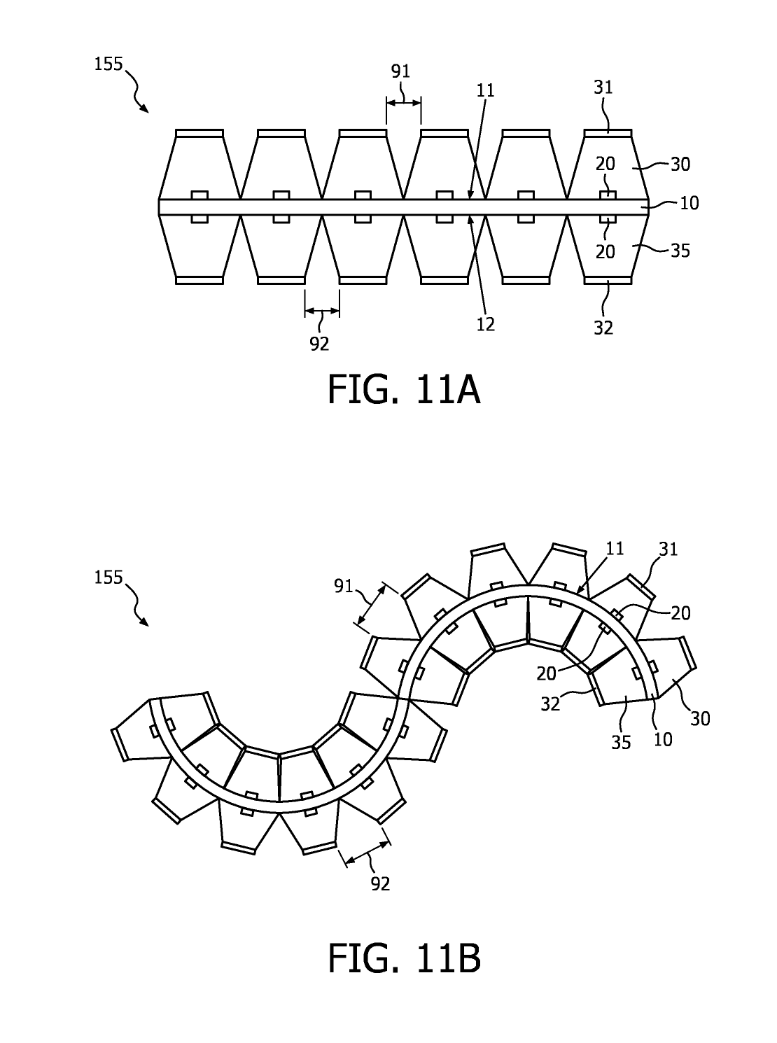

FIGS. 11A and 11B show schematic drawings of different shapes of a light emitting device 155 according to an embodiment the invention. The difference with the embodiments shown in FIG. 2 is that additionally second optical elements 35, in this case pyramid or cone shaped, are provided on a second surface 12 of the flexible and at least partly transparent substrate 10, which second surface 12 is opposite to the first surface 11 of the flexible substrate 10 and faces the second light exit window. Further reflective elements 32 are provided on the flattened top surfaces of the second optical elements 35. Furthermore, in this embodiment the light emitting diodes 20 are also arranged on the second surface 12 of the flexible substrate 10. However, in another embodiment (not shown) light emitting diodes 20 are only arranged on the first surface 11 of the flexible substrate 10. The light that is redirected by the reflective elements 31 provided on the first optical elements 30 and transmitted through the translucent and flexible substrate 10 is partly affected by the plurality of second optical elements 35 and the further reflective elements 32. Furthermore, similarly light that is emitted by the light emitting diodes 20 arranged on the second surface 12 of the flexible substrate 10 and that is redirected by the further reflective elements 32 arranged on the second optical elements 35 is transmitted at least partly through the translucent substrate 10 in a direction of the first light exit window and will at least partly be affected by the first optical elements 30 and the reflective elements 31. Thus, light that is emitted via the first light exit window is a combination of light emitted by the light emitting diodes 20 arranged on the first surface 11 of the flexible substrate 10 and light emitted by the light emitting diodes 20 arranged on the second surface 12 of the flexible substrate 10 and redirected by the further reflective elements 32. Similarly, light that is emitted via the second light exit window is a combination of light emitted by the light emitting diodes 20 arranged on the second surface 12 of the flexible substrate 10 and light emitted by the light emitting diodes 20 arranged on the first surface 11 of the flexible substrate 10 and redirected by the reflective elements 31. In this case the light emitting device generates two light beams in two substantially opposite directions in which at least one optical property of each of the light beam can be tuned or affected by changing the shape of the flexible substrate.

FIG. 11B shows a fourth shape of the light emitting device 155 in which the flexible substrate is wave-shaped, i.e. flexed or bended in two opposite directions. The distance 91 between the first optical elements 30, and the reflective elements 31, varies along/over the flexible substrate (and may even be zero at specific locations), and, similarly, the distance 92 between the second optical elements 35, and the further reflective elements 32 varies (and may even be zero at specific locations) and thus both the first and the second distances vary. In this way a specific shape of the flexible substrate 10 of the light emitting device 155 provides for a variation of the optical characteristics over the first and second light exit windows, because the optical characteristics of the plurality of first optical elements 30 and of the plurality of second optical elements 35 vary along/over the flexible substrate 10. In other words, one or more optical characteristics or properties, or a value of an optical parameter, is position dependent.

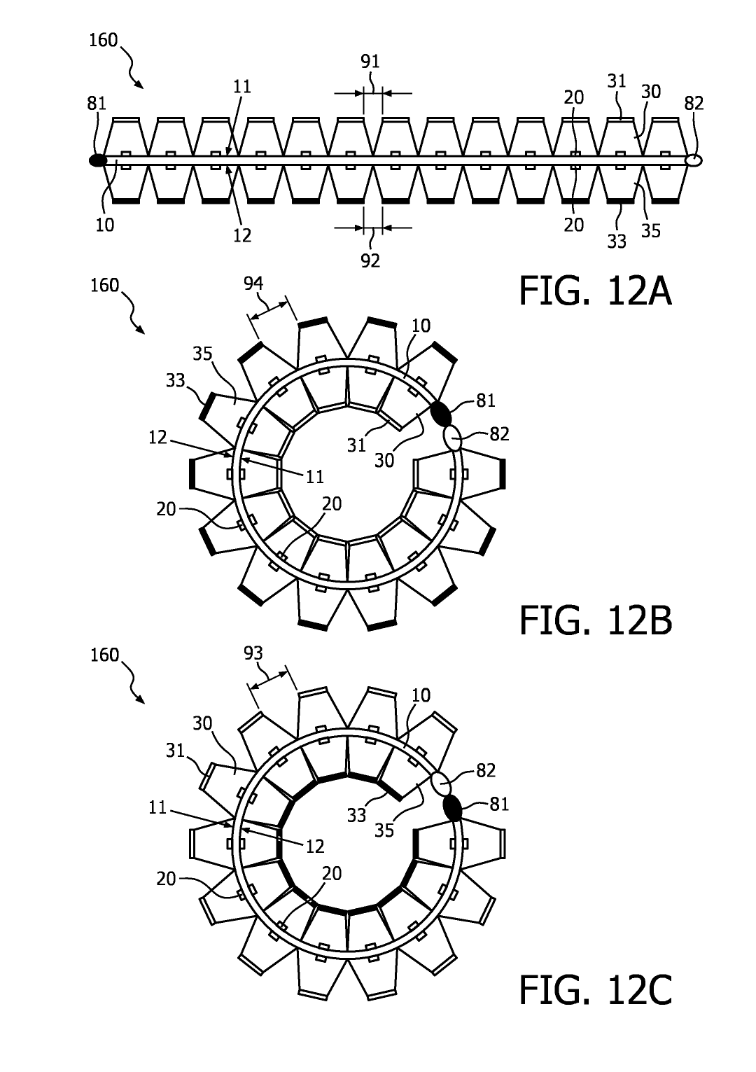

FIGS. 12A, 12B and 12C show schematic drawings of different shapes of a light emitting device 160 according to an embodiment the invention. The differences with the light emitting device 155 shown in FIGS. 11A, 11B are that the further reflective elements 32 are replaced by wavelength converting elements 33 and that first and second connection means or connectors 81, 82 are provided at opposite ends of the flexible substrate 10. The first and second connectors 81, 82 are arranged to be fixated, or mechanically connected, to each other such that a specific shape of the flexible substrate 10 is fixated by the mechanical connection provided by the connected connectors 81, 82. The first and second connectors 81, 82 comprise, for example, a first and a second magnet, a mechanical connector, such as a click connection, and/or a glue.

FIG. 12A shows a schematic drawing of an initial shape of the flexible substrate 10 of the light emitting device 160, which is a generally flat shape in which the first optical elements 30 and the reflective elements 31 are spaced with a first distance 91 and the second optical elements 35 and the wavelength converting elements 33 are spaced with a second distance 92.

FIG. 12B shows a first, flexed or bended, shape of the flexible substrate 10 which corresponds in this case to a generally cylindrical shape in which the wavelength converting elements 33 are located at an outer surface of the generally cylindrical shape and the reflective elements 31 are located at an inner surface of the generally cylindrical shape. The wavelength converting elements 33 are spaced with a fourth distance 94, which is different from the second distance 92 of the initial shape of the flexible substrate 10. In this example the first optical elements 30 and the reflective elements 31 are adjoining, i.e. the distance between neighboring first optical elements 30 and neighboring reflective elements 31 is zero. However, in another embodiment this distance is larger than zero, but less than the second distance 92 defined by the initial shape. This first flexed shape of the flexible substrate 10 is fixated by connecting the first and the second connection means or connectors 81, 82, which provides for a rigid and reliable construction of this first flexed shape of the light emitting device 160.

FIG. 12C shows an analogous and second, flexed or bended, shape of the flexible substrate 10 which corresponds to a generally cylindrical shape which is the inverse of the embodiment of FIG. 12B, because in this embodiment the wavelength converting elements 33 located at the inner surface of the generally cylindrical shape and the reflective elements 31 are located at the outer surface of the generally cylindrical shape. The reflective elements 31 are spaced with a third distance 94, which is different from the first distance 91 of the initial shape of the flexible substrate 10. In this example the second optical elements 35 and the wavelength converting elements 33 are adjoining, i.e. the distance between neighboring second optical elements 35 and neighboring wavelength converting elements 33 is zero. However, in another embodiment this distance is larger than zero, but less than the first distance 91 defined by the initial shape. This second flexed shape of the flexible substrate 10 is also fixated by connecting the first and the second connection means or connectors 81, 82, which provides for a rigid and reliable construction of this second flexed shape of the light emitting device 160.

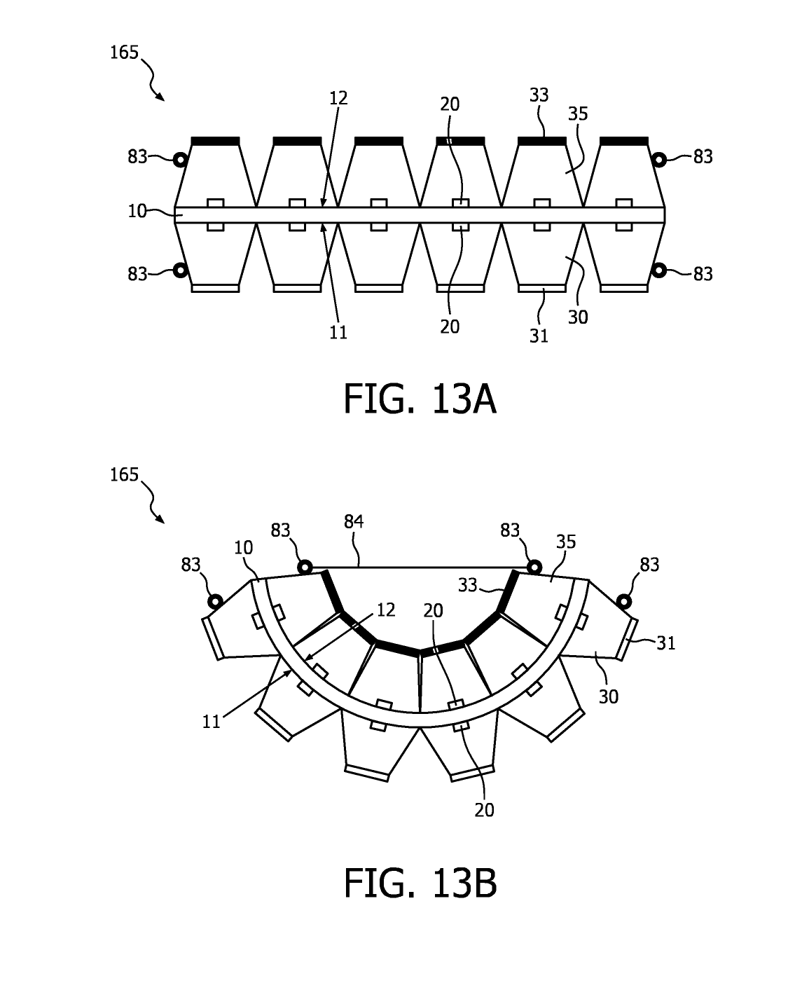

FIGS. 13A and 13B show schematic drawings of different shapes of a light emitting device 165 according to an embodiment the invention. The difference with the light emitting device 160 shown in FIGS. 12A, 12B, 12C are that third connection means or connectors 83 are arranged on the first and second optical elements 30, 35 that are arranged at opposite ends of the flexible substrate 10. The third connectors 83 are arranged such that opposite connectors can be mechanically connected via a fourth connection means or connector 84. The third connection means or connectors 83 for example comprise eyes and the fourth connection means or connector 84 for example comprise a rope which is fixated to two opposite third connectors 83, as is shown in FIG. 13B which shows a generally semi-cylindrical or arc-like shape of the flexible substrate 10 that is fixated by the third and fourth connectors. Analogously, the third connectors 83 that are arranged at or on the second optical structures 35 can be mechanically connected via the fourth connector 84 resulting in another fixated shape of the light emitting device 165 (not shown). By changing the length of the fourth connector 84, the distance between the opposite ends of the flexible substrate 10 is changed and another predefined shape of the flexible substrate 10 is fixated. The connectors in this case thus comprises means to adapt the distance between opposite ends of the flexible substrate 10. In case the fourth connection means or connector 84 is a rope, it avoids that the flexible substrate 10 bends or flexes back to its original or initial state. The fourth connection means or connector 84 may in another embodiment comprise a rigid rod or a wire.

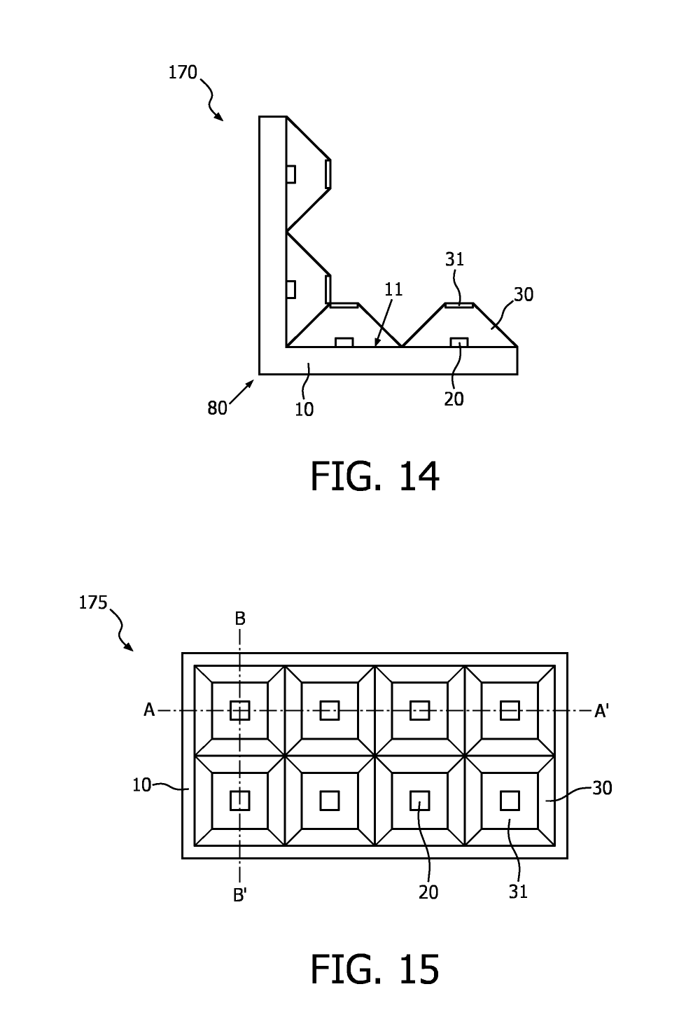

FIG. 14 shows a schematic drawing of a cornered shape of a light emitting device 170 according to an embodiment the invention. The difference with the light emitting device 100 shown in FIG. 2 is the cornered shape of the flexible substrate 10 in which the flexible substrate 10 is flexed to provide a shape of the flexible substrate 10 which comprises an angled corner 80 with, in this example having an angle of 90 degrees. The angled corner of 90 degrees divides the substrate into two flat regions separated by the 90 degrees corner 80.

FIG. 15 shows a top view of a light emitting device 175 according to an embodiment of the invention. Similar to the embodiments shown in FIG. 2 the light emitting device 175 comprises pyramid shaped first optical elements 30 comprising reflective elements 31 on a flattened top surface and light emitting diodes 20 provided on the first surface of the flexible and at least partly transparent substrate 10. In another embodiment (not shown) wavelength converting elements are provided instead of the reflective elements. The schematic top view projects onto the first surface of the flexible substrate 10. In this example the plurality of light emitting diodes 20 and the plurality of first optical elements 30, comprising the reflective elements 31, are both arranged as a 2-dimensional array, in which neighboring first optical elements 30 adjoin each other at the base or bottom surface. This embodiment of the invention provides for an additional degree of freedom to change the optical characteristics of the light emitting device 175, because the flexible substrate 10 can be flexed or bended in two directions, simultaneously or separately, as indicated by dotted lines A-A′ and B-B′. By flexing the flexible substrate 10 around A-A′, the distance between neighboring or adjacent first optical elements 30 in the direction B-B′ is changed. Similarly, by flexing the flexible substrate 101 around B-B′, the distance between neighboring or adjacent first optical elements 30 in the direction A-A′ is changed. This 2-dimensional array lay-out can also be applied to the other, above described, embodiments.

The above described embodiments are some examples of a light emitting device according to the invention. Different combinations can be made that are within the scope of the invention, such as differently shaped first and second optical elements, combining wavelength converting elements with reflective elements, etc. For example the first optical elements may be a combination of or at least partly a dichroic reflector, specular reflector, diffusor, wavelength convertor, refractor, and/or a diffractor. Furthermore, there may be layers provided on the first optical elements that are any one of diffractive, refractive, reflective, scattering, and/or wavelength converting. Also, the flexible substrate may be reflective in case only one light exit window is required, and it may be at least partly transparent in case two different and opposite light exit windows are required. Driver electronics for the flexible light source may be for example be provided on the reflective elements that are provided on the first and/or second optical elements. The devices herein are amongst others described during operation. As will be clear to the person skilled in the art, the invention is not limited to methods of operation or devices in operation.

In the claims, the word “comprising” does not exclude other elements or steps, and the indefinite article “a” or “an” does not exclude a plurality. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measured cannot be used to advantage.

1. A light emitting device for emitting two light beams in two substantially opposite directions, the light emitting device comprising:
a flexible light source having a first surface facing a first light exit window and a second surface facing a second light exit window, the second surface being opposite to the first surface, the flexible light source being at least partly transparent, and
a plurality of first optical elements provided on the first surface of the flexible light source and arranged to change a value of at least one optical parameter of at least a part of the light emitted by the flexible light source,
wherein the flexible light source is arranged to emit light at least in a direction of the first light exit window, and wherein the plurality of first optical elements is arranged to redirect at least a part of the light emitted by the flexible light source in a direction of the second light exit window,
wherein a distance between adjacent first optical elements depends on a shape of the flexible light source, and
wherein for each of the two light beams the value of the at least one optical parameter of at least part of the light emitted by the light emitting device is different for a first shape of the flexible light source as compared to a second shape of the flexible light source, the first shape being different from the second shape.

2. (canceled)

3. The light emitting device according to claim 1, wherein the flexible light source comprises a flexible light guide and wherein a plurality of outcoupling structures, are provided at or on the first surface of the flexible light guide

4. The light emitting device according to claim 1, wherein the flexible light source comprises a plurality of solid state light sources provided on a flexible substrate.

5. (canceled)

6. The light emitting device according to claim 1, wherein at least one of the plurality of first optical elements comprises a reflective element.

7. The light emitting device according to claim 1, wherein at least one of the plurality of first optical elements comprises a wavelength converting element.

8. The light emitting device according to claim 1, wherein at least one of the plurality of first optical elements is reflective for a first range of wavelengths and transmissive for a second range of wavelengths which is different from the first range of wavelengths.

9. The light emitting device according to claim 1, further comprising a plurality of second optical elements on the second surface of the flexible light source, and wherein a distance between adjacent second optical elements depends on the shape of the flexible light source.

10. The light emitting device according to claim 1, wherein the first optical elements have a pyramid or cone shape with a flattened top surface and wherein a base of the pyramid or cone shape is arranged on the first surface of the flexible light source, wherein the distance between adjacent first optical elements is defined by the spacing between the flattened top surfaces.

11. The light emitting device according to claim 1, wherein the flexible light source is adapted to be shaped as a cylindrical shape.

12. The light emitting device according to claim 1, wherein the plurality of first optical elements are arranged in a 2-dimensional array.

13. The light emitting device according to claim 1, further comprising connection means arranged to fixate a predefined shape of the flexible light source.

14. The light emitting device according to claim 1, wherein the flexible light source is further arranged to also emit light into a direction of the second light exit window and wherein a value of at least one optical parameter of light emitted by the light emitting device via the second light exit window is different for the first shape of the flexible light source as compared to the second shape of the flexible light source.

15. A luminaire comprising a light emitting device according to claim 1.
